(19) United States
(12) Patent Application Publication
(10) Pub. No.: US 2016/0086805 A1
(43) Pub. Date: Mar. 24, 2016

(54) METAL-GATE WITH AN AMORPHOUS METAL LAYER

(71) Applicant: QUALCOMM Incorporated, San Diego, CA (US)

(72) Inventors: Jeffrey Junhao Xu, San Diego, CA (US); Zhongze Wang, San Diego, CA (US); Kern Rim, San Diego, CA (US); Stanley Seungchul Song, San Diego, CA (US); Choh Fei Yeap, San Diego, CA (US)

(21) Appl. No.: 14/626,293

(22) Filed: Feb. 19, 2015

Related U.S. Application Data
(60) Provisional application No. 62/054,851, filed on Sep. 24, 2014.

(51) Int. Cl. H01L 21/28; H01L 21/306; H01L 29/49; H01L 29/78; H01L 29/66

(52) U.S. Cl. CPC H01L 21/28079; H01L 29/78; H01L 29/66636; H01L 29/495; H01L 21/30604

(57) ABSTRACT

A particular semiconductor device includes a substrate, a source contact, a drain contact, and a metal-gate. The substrate includes a source region, a drain region, and a channel. The source contact is coupled to the source region. The drain contact is coupled to the drain region. The metal-gate is coupled to the channel. The metal-gate includes an amorphous metal layer.

### I. CLAIM OF PRIORITY

The present application claims priority to and the benefit of U.S. Provisional Patent Application No. 62/054,851, filed Sep. 24, 2014, the content of which is expressly incorporated herein by reference in its entirety.

### II. FIELD

The present disclosure is generally related to a metal-gate with an amorphous metal layer.

### III. DESCRIPTION OF RELATED ART

Advances in technology have resulted in smaller and more powerful computing devices. For example, a variety of portable personal computing devices, including wireless telephones such as mobile and smart phones, tablets and laptop computers, are small, lightweight, and easily carried by users. These devices can communicate voice and data packets over wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing capabilities.

To enable the computing capabilities, the computing devices include processors. As technology advances, these processors include more and more devices (e.g., transistors) and the devices become smaller. A smaller device (e.g., a metal-gate transistor) may include a smaller metal-gate. An orientation of metal grains within a smaller metal-gate may have a larger relative effect on work function, as compared to a larger metal-gate. Work function may be defined as a minimum energy to remove an electron from a solid surface. The work function of a metal-gate may depend on an orientation of metal grains within the metal-gate.

Polycrystalline gate materials may have differences in grain orientation. For example, grain orientation may vary within a metal-gate formed of the polycrystalline gate material. A metal-gate made from the polycrystalline gate materials may thus have work function variation.

Amorphous (i.e., non-crystalline) metals may be used to form metal-gate transistors to reduce work function variation. High temperature annealing used to stabilize a metal-gate transistor structure may cause the amorphous metals to crystallize (i.e., not remain amorphous). Thus, the resulting metal-gate transistors may have work function variation. Work function variation may be a source of threshold voltage (Vt) fluctuation in metal-gate transistors. The Vt fluctuation may result in the metal-gate transistors having a higher supply voltage (Vdd). For example, Vt of a metal-gate transistor may range from a minimum Vt to a maximum Vt. The Vdd is higher than the maximum Vt. A higher work function variation may result in a higher maximum Vt. A higher maximum Vt results in a higher Vdd, and higher Vdd typically causes greater power consumption.

### IV. SUMMARY

Metal-gate transistors may be formed of materials that are stable without performing annealing. Using such materials to form metal-gate transistors may enable amorphous metals to remain amorphous in resulting metal-gate transistors. For example, a semiconductor device may include a substrate, a source contact, a drain contact, and a metal-gate. The substrate may include a source region, a drain region, and a channel. A source contact may be coupled to the source region and a drain contact may be coupled to the drain region. The metal-gate may be coupled to the channel. The metal-gate may include an amorphous metal layer. The amorphous metal layer may have an annealing temperature at which the amorphous metal layer crystallizes.

The semiconductor device may be formed of materials that are stable without performing annealing. For example, the source contact and the drain contact may be formed by depositing a material (e.g., titanium (Ti)) on the source region and the drain region such that a temperature of the amorphous metal layer remains below the crystallization temperature. The amorphous metal layer of the semiconductor device (e.g., a metal-gate transistor) may thus remain amorphous (due to no annealing and no crystallization). The metal-gate may thus have reduced work function variation. For example, a difference between a first work function of a first portion of the metal-gate and a second work function of a second portion of the metal-gate may be reduced. In a particular embodiment, work function variation across multiple metal-gates may also be reduced. For example, a difference between a first work function of a first amorphous metal-gate and a second work function of a second amorphous metal-gate may be reduced. The reduced work function variation may result in a reduced maximum Vt. A lower maximum Vt may result in a lower Vdd and reduced power consumption.

In a particular aspect, a semiconductor device includes a substrate, a source contact, a drain contact, and a metal-gate. The substrate includes a source region, a drain region, and a channel. The source contact is coupled to the source region. The drain contact is coupled to the drain region. The metal-gate is coupled to the channel. The metal-gate includes an amorphous metal layer.

In another particular aspect, a method of fabricating a semiconductor device includes forming a metal-gate on a substrate. The metal-gate includes an amorphous metal layer. The method also includes depositing a second material on a source region and a drain region of the substrate. The second material is deposited such that the amorphous metal layer remains amorphous.

In another particular aspect, a semiconductor device is fabricated by a process that includes forming a metal-gate on a substrate. The metal-gate includes an amorphous metal layer. The process also includes depositing a second material on a source region and a drain region of the substrate. The second material is deposited such that the amorphous metal layer remains amorphous.

One particular advantage provided by at least one of the disclosed embodiments is a metal-gate having an amorphous metal layer. The amorphous metal layer may result in reduced work function variation, a lower supply voltage (Vdd), and reduced power consumption.

Other aspects, advantages, and features of the present disclosure will become apparent after review of the entire application, including the following sections: Brief Description of the Drawings, Detailed Description, and the Claims.

### V. BRIEF DESCRIPTION OF THE DRAWINGS

FIG. 1 is a diagram of a side view of an illustrative embodiment of a structure during at least one stage in a process of fabricating an electronic device;

FIG. 2 is a diagram of a side view of the structure of FIG. 1 during at least one stage in a process of fabricating an electronic device;

FIG. 3 is a diagram of a side view of the structure of FIG. 1 during at least one stage in a process of fabricating an electronic device;

FIG. 4 is a diagram of a side view of the structure of FIG. 1 during at least one stage in a process of fabricating an electronic device;

FIG. 5 is a diagram of a side view of the structure of FIG. 1 during at least one stage in a process of fabricating an electronic device;

FIG. 6 is a diagram of a side view of the structure of FIG. 1 during at least one stage in a process of fabricating an electronic device;

FIG. 7 is a diagram of a side view of the structure of FIG. 1 during at least one stage in a process of fabricating an electronic device;

FIG. 8 is a diagram of a side view of the structure of FIG. 1 during at least one stage in a process of fabricating an electronic device;

FIG. 9 is a diagram of a side view of the structure of FIG. 1 during at least one stage in a process of fabricating an electronic device;

FIG. 10 is a diagram of a side view of the structure of FIG. 1 during at least one stage in a process of fabricating an electronic device;

FIG. 11 is a diagram of a side view of the structure of FIG. 1 during at least one stage in a process of fabricating an electronic device;

FIG. 12 is a diagram of a side view of the structure of FIG. 1 during at least one stage in a process of fabricating an electronic device;

FIG. 13 is a diagram of a side view of the structure of FIG. 1 during at least one stage in a process of fabricating an electronic device;

FIG. 14 is a diagram of an illustrative embodiment of a static random access memory (SRAM) device that includes the structure of FIG. 13;

FIG. 15 is a flow chart that illustrates a method of fabricating a semiconductor device;

FIG. 16 is a block diagram of a wireless communication device including a semiconductor device having an amorphous metal-gate; and

FIG. 17 is a data flow diagram of a particular illustrative embodiment of a manufacturing process to manufacture electronic devices that include a semiconductor device having an amorphous metal-gate.

### VI. DETAILED DESCRIPTION

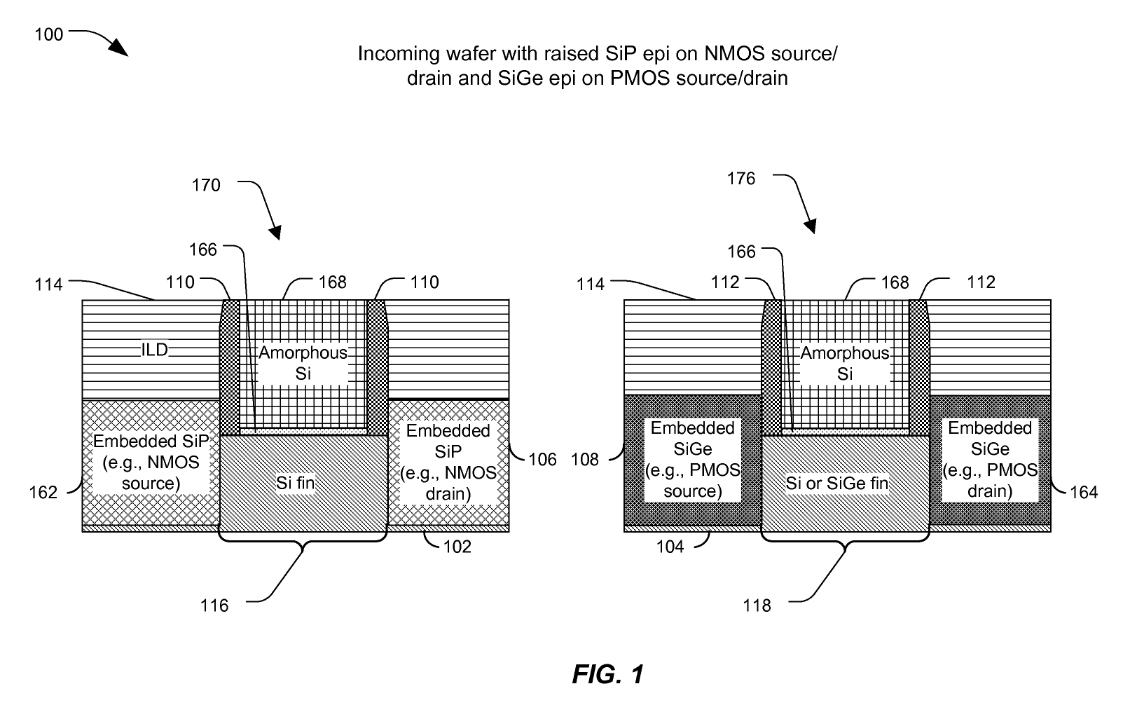

FIGS. 1-13, as described herein, illustrate a side view of a structure as formed during multiple stages of a process of fabricating an electronic device (e.g., a semiconductor device, an integrated circuit device, or another electronic device).

Referring to FIG. 1, a diagram of a side view of a structure as formed during a process of fabricating an electronic device is disclosed and generally designated 100. The structure 100 may be formed using a wafer that includes a first substrate (e.g., a silicon (Si) fin 102) and a second substrate (e.g., a Si or Si germanium (SiGe) fin 104).

The structure 100 may include a drain region 106, a source region 162, and a channel 116. For example, the drain region 106 may include a silicon phosphorous (SiP) layer embedded in a first portion of the Si fin 102. The source region 162 may include a silicon phosphorous (SiP) layer embedded in a second portion of the Si fin 102. The channel 116 may include the Si fin 102 between the source region 162 and the drain region 106.

The structure 100 may include a drain region 164, a source region 108, and a channel 118. For example, the source region 108 may include a SiGe layer embedded in a first portion of the Si or SiGe fin 104. The drain region 164 may include a SiGe layer embedded in a second portion of the Si or SiGe fin 104. The channel 118 may include the Si or SiGe fin 104 between the source region 108 and the drain region 164.

The structure 100 may include an inter-layer dielectric (ILD) 114 on the drain region 106, on the source region 162, on the source region 108, and on the drain region 164. The structure 100 may include silicon mononitride (SiN) spacers 110 on a portion of the Si fin 102 and may include SiN spacers 112 on a portion of the Si or SiGe fin 104. The structure 100 may include a first dummy gate 170. For example, the first dummy gate 170 may include a dummy liner 166 and an amorphous Si layer 168 between the SiN spacers 110. The structure 100 may include a second dummy gate 176. For example, the second dummy gate 176 may include the dummy liner 166 and the amorphous Si layer 168 between the SiN spacers 112.

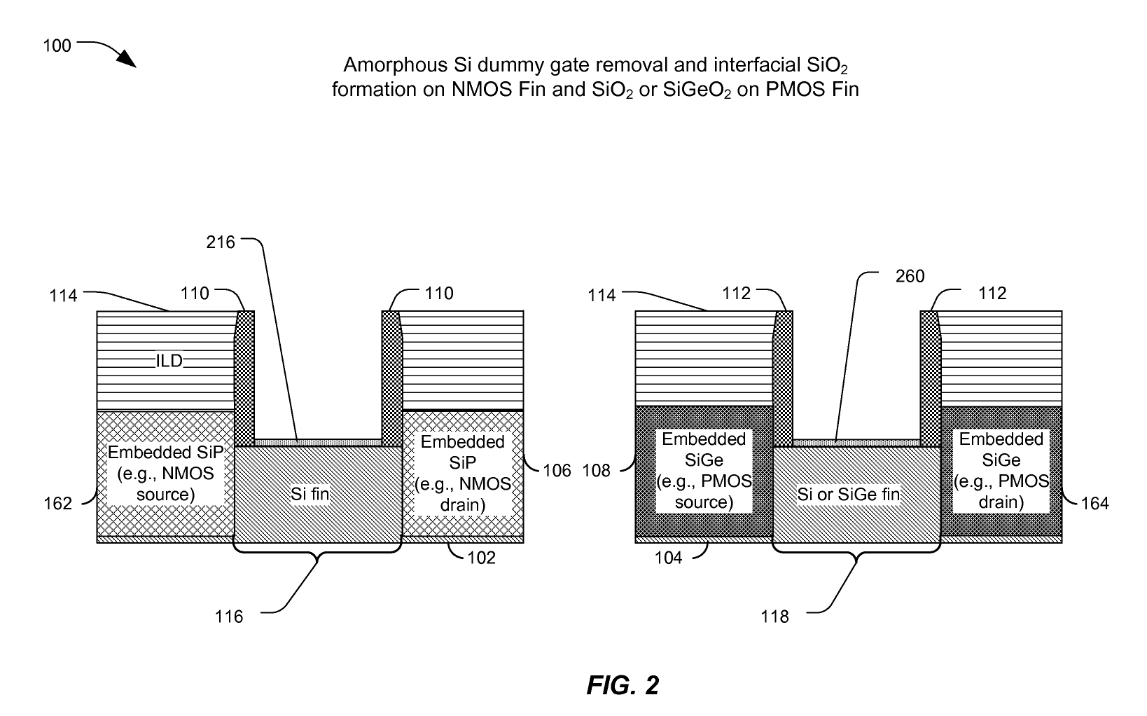

Referring to FIG. 2, a diagram of a side view of a structure as formed during a process of fabricating an electronic device is disclosed. The first dummy gate 170 and the second dummy gate 176 may be removed (e.g., etched) from the structure 100. Subsequent to removal of the first dummy gate 170, a native silicon dioxide (SiO₂) layer 216 may form on the Si fin 102 between the SiN spacers 110. Subsequent to removal of the second dummy gate 176, a native silicon dioxide (SiO₂) or silicon germanium dioxide (SiGeO₂) layer 260 may form on the Si or SiGe fin 104 between the SiN spacers 112.

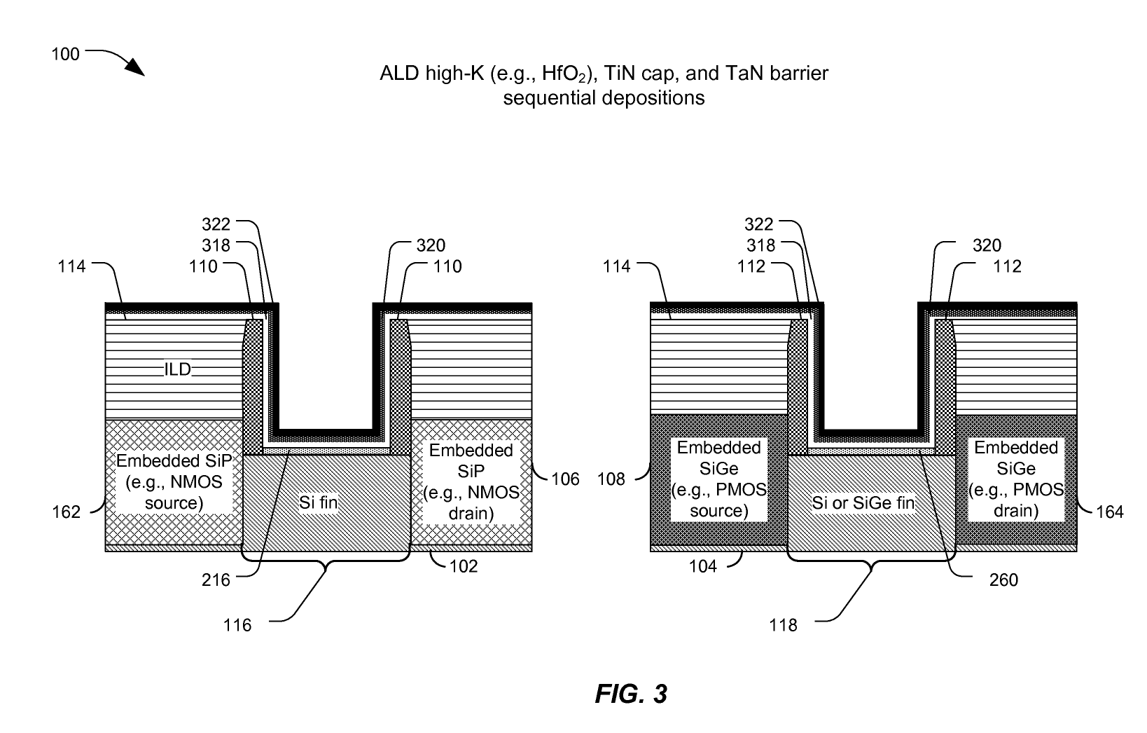

Referring to FIG. 3, a diagram of a side view of a structure as formed during a process of fabricating an electronic device is disclosed. A high dielectric constant (high-K) layer 318 (e.g., a hafnium dioxide (HfO₂) layer) may be deposited on the structure 100. For example, the high-K layer 318 may be deposited on the structure 100 subsequent to formation of the native layers 216 and 260. A titanium nitride (TiN) cap layer 320 may be deposited on the high-K layer 318, and a tantalum nitride (TaN) barrier layer 322 may be deposited on the TiN cap layer 320. The high-K layer 318 may be deposited using atomic layer deposition (ALD).

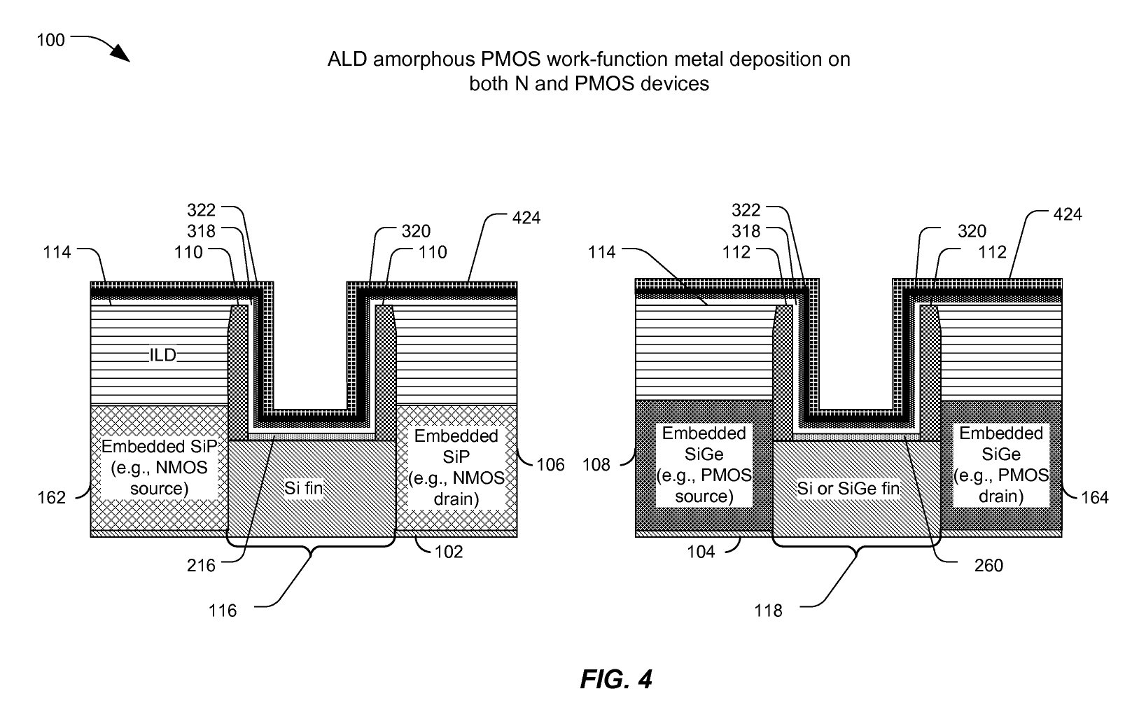

Referring to FIG. 4, a diagram of a side view of a structure as formed during a process of fabricating an electronic device is disclosed. An amorphous p-type metal oxide semiconductor (PMOS) work-function metal layer 424 may be deposited on the structure 100. For example, the amorphous PMOS work-function metal layer 424 may be deposited on the structure 100 subsequent to the deposition of the TaN barrier layer 322. The amorphous PMOS work-function metal layer 424 may include a metal, a metal alloy (e.g., a compound with a plurality of metals or a compound with at least one metal and at least one non-metal), or an intermetallic layer. The amorphous PMOS work-function metal layer 424 may include at least one of tungsten (W), tantalum (Ta), aluminum (Al), cobalt (Co), titanium (Ti), and platinum (Pt). In addition, the amorphous PMOS work-function metal layer 424 may include one or more of silicon (Si), carbon (C), and nitrogen (N),

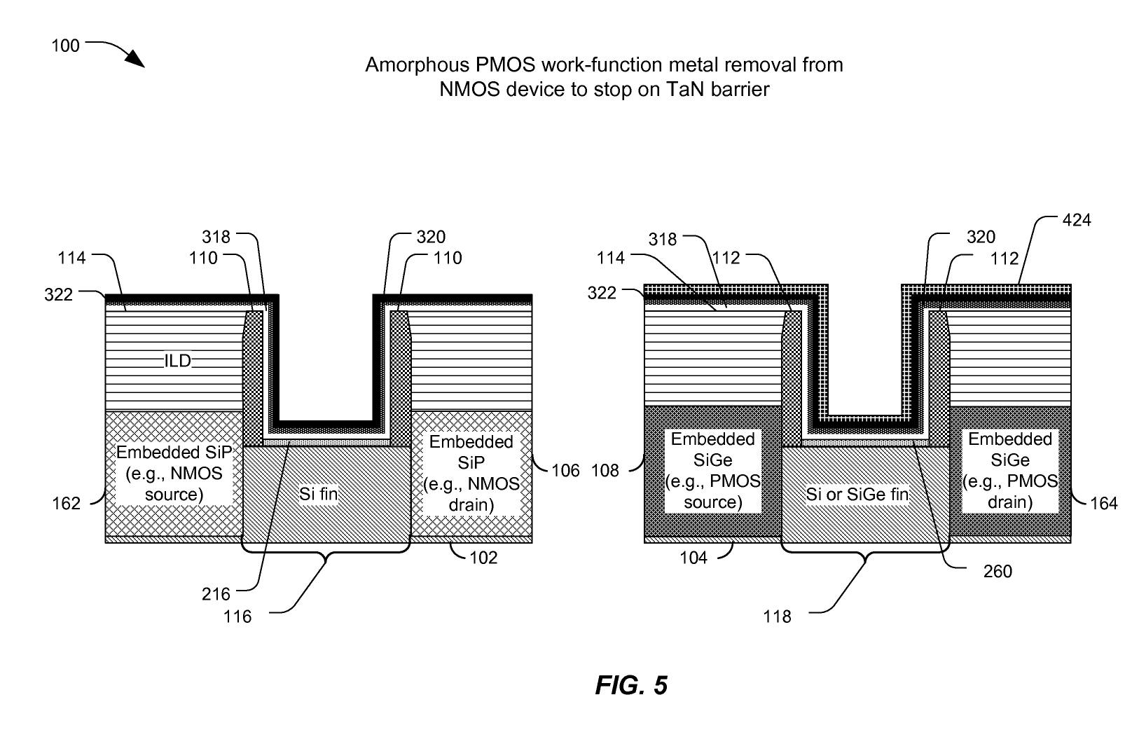

Referring to FIG. 5, a diagram of a side view of a structure as formed during a process of fabricating an electronic device is disclosed and generally designated 500. A portion of the amorphous PMOS work-function metal layer 424 may be removed (e.g., etched) from the structure 100. For example, a first portion of the amorphous PMOS work-function metal layer 424 that is aligned with the Si fin 102 may be removed. As another example, a second portion of the amorphous PMOS work-function metal layer 424 that is aligned with the Si or SiGe fin 104 may remain (e.g., may not be etched).

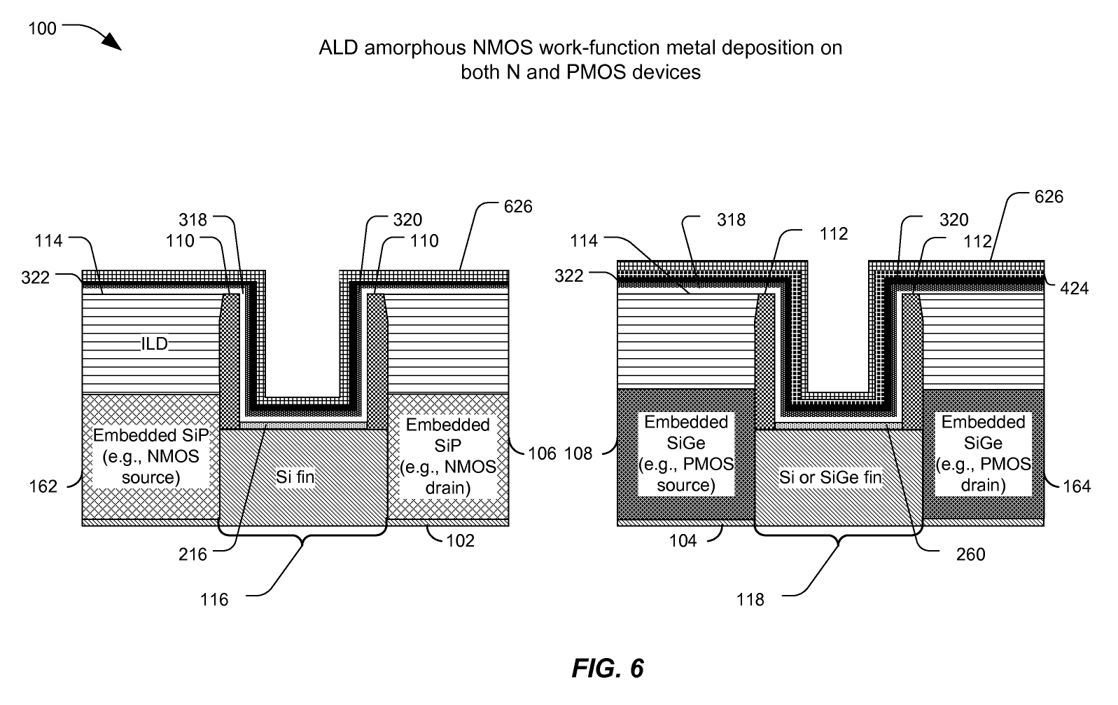

Referring to FIG. 6, a diagram of a side view of a structure as formed during a process of fabricating an electronic device is disclosed. An amorphous n-type metal oxide semiconductor (NMOS) work-function metal layer 626 may be deposited on the structure 100. For example, the amorphous NMOS work-function metal layer 626 may be deposited using ALD subsequent to removal of the portion of the amorphous PMOS work-function metal layer 424, as described with reference to FIG. 5. The amorphous NMOS work-function metal layer 626 may include a metal, a metal alloy (e.g., a compound with a plurality of metals or a compound with at least one metal and at least one non-metal), or an intermetallic layer. The amorphous NMOS work-function metal layer 626 may include at least one of tantalum (Ta), aluminum (Al), and titanium (Ti). In addition, the amorphous NMOS work-function metal layer 626 may include one or more of silicon (Si), carbon (C), and nitrogen (N).

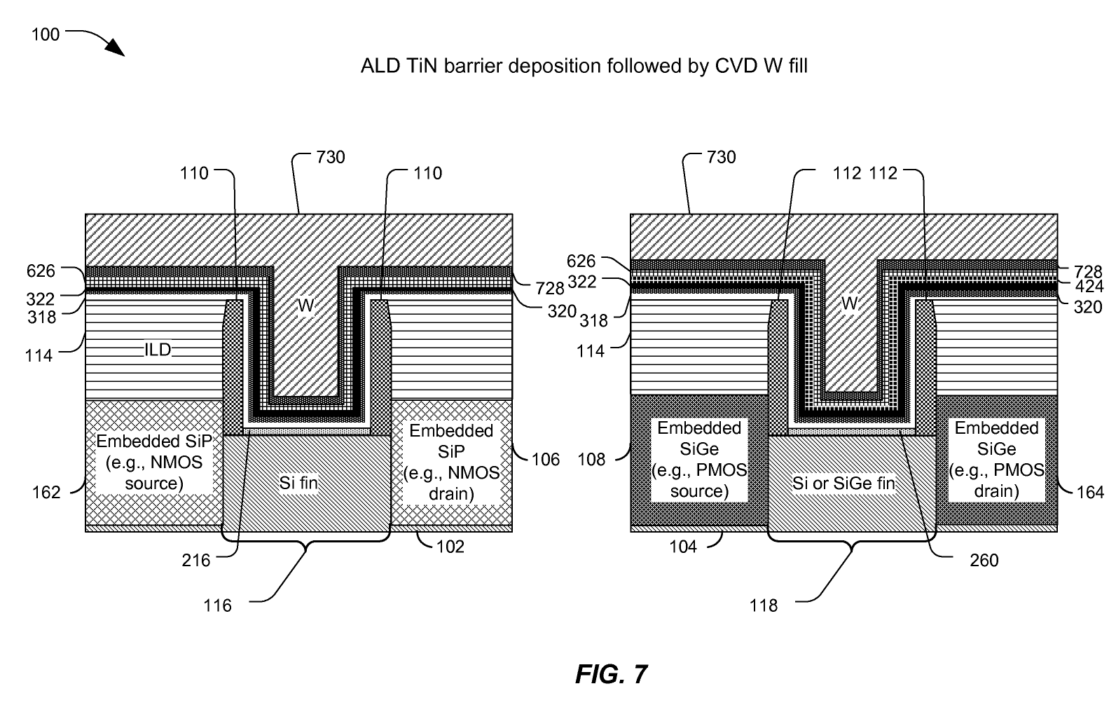

Referring to FIG. 7, a diagram of a side view of a structure as formed during a process of fabricating an electronic device is disclosed. A TiN barrier layer 728 may be deposited on the structure 100. For example, the TiN barrier layer 728 may be deposited on the amorphous NMOS work-function metal layer 626 using ALD. Subsequent to deposition of the TiN barrier layer 728, a tungsten (W) layer 730 may be deposited on the structure 700 using chemical vapor deposition (CVD).

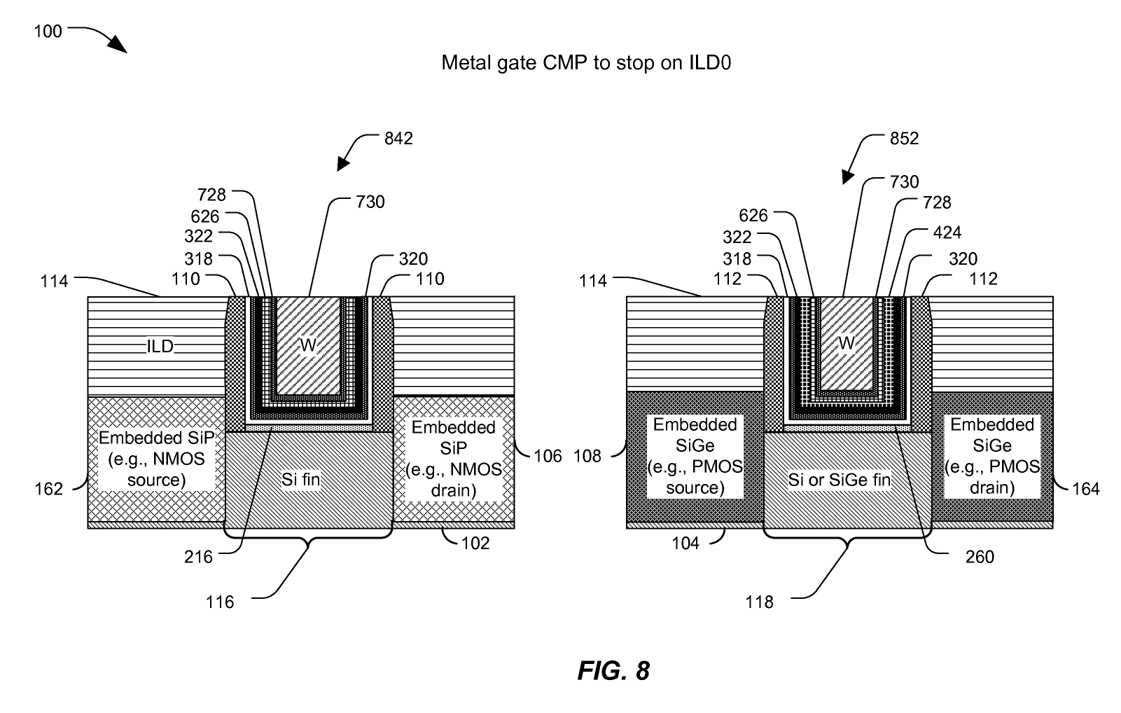

Referring to FIG. 8, a diagram of a side view of a structure as formed during a process of fabricating an electronic device is disclosed. Chemical mechanical planarization (CMP) may be performed on the structure 100. For example, a metal-gate 842 (e.g., the SiO₂ layer 216, the high-K layer 318, the TiN cap layer 320, the TaN barrier layer 322, the amorphous NMOS work-function metal layer 626, the TiN barrier layer 728, and the tungsten (W) layer 730) and a metal-gate 852 (e.g., the SiO₂ or SiGeO₂ layer 260, the high-K layer 318, the TiN cap layer 320, the TaN barrier layer 322, the amorphous PMOS work-function metal layer 424, the amorphous NMOS work-function metal layer 626, the TiN barrier layer 728, and the tungsten (W) layer 730) may be formed by performing CMP subsequent to deposition of the tungsten (W) layer 730.

The amorphous NMOS work-function metal layer 626 may begin to crystallize (e.g., during a silicidation process) at a temperature (e.g., a first annealing temperature) typically greater than 600 degrees Celsius. The materials used to form the amorphous NMOS work-function metal layer 626 may include at least one of tantalum (Ta), aluminum (Al), and titanium (Ti). The materials used to form the amorphous NMOS work-function metal layer 626 may also include one or more of silicon (Si), carbon (C), and nitrogen (N).

The amorphous PMOS work-function metal layer 424 may, alternatively or in addition, begin to crystallize (e.g., during a silicidation process) at a temperature (e.g., a second annealing temperature) typically greater than 600 degrees Celsius. The materials used to form the amorphous PMOS work-function metal layer 424 may include at least one of tungsten (W), tantalum (Ta), aluminum (Al), cobalt (Co), titanium (Ti), and platinum (Pt). The materials used to form the amorphous PMOS work-function metal layer 424 may also include one or more of silicon (Si), carbon (C), and nitrogen (N).

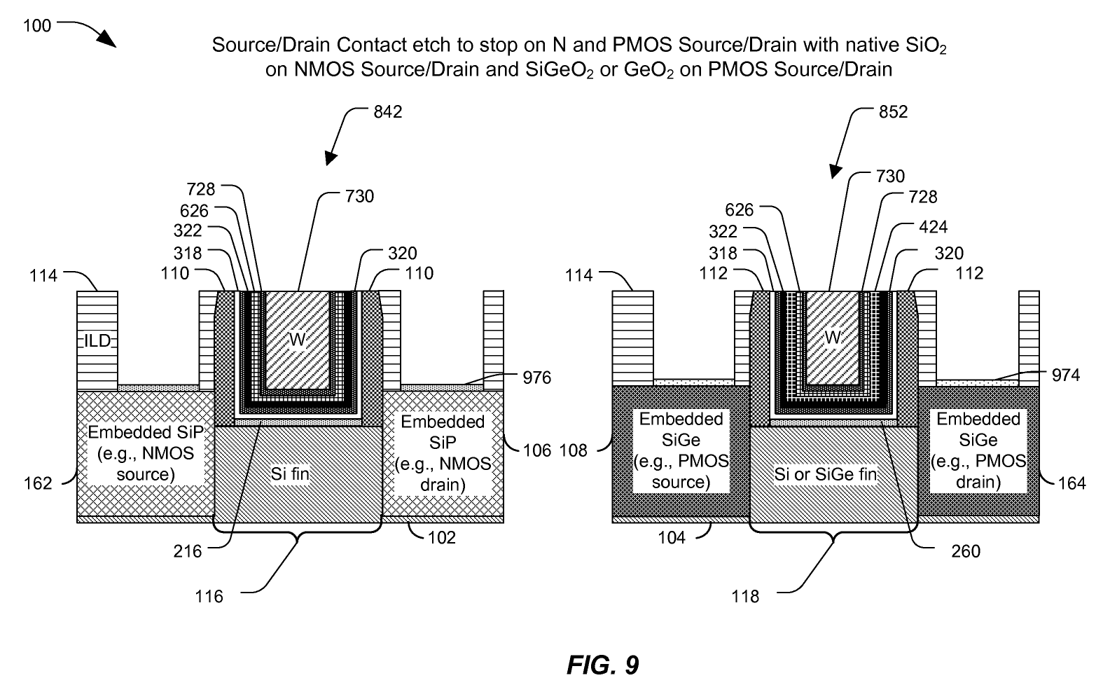

Referring to FIG. 9, a diagram of a side view of a structure as formed during a process of fabricating an electronic device is disclosed. The structure 100 may be etched. For example, first portions of the ILD 114 may be etched to the drain region 106 and the source region 162. Second portions of the ILD 114 may be etched to the source region 108 and the drain region 164. A native SiO₂ layer 976 may form on exposed portions of the drain region 106 and the source region 162 subsequent to etching of the ILD 114. A native SiGeO₂ or germanium dioxide (GeO₂) layer 974 may form on exposed portions of the source region 108 and the drain region 164 subsequent to etching of the ILD 114.

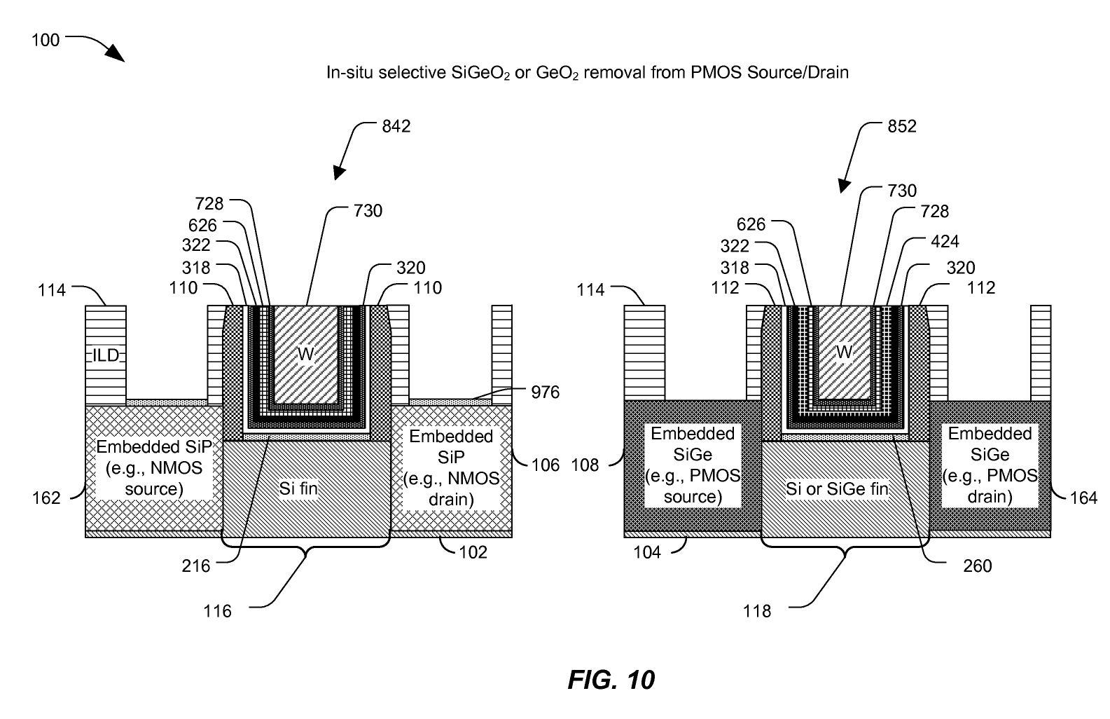

Referring to FIG. 10, a diagram of a side view of a structure as formed during a process of fabricating an electronic device is disclosed. In-situ selective removal may be performed on the structure 100. For example, the native SiGeO₂ or GeO₂ layer 974 may be removed by in-situ selective removal. To illustrate, chemical etching or ion etching may be performed to selectively remove the native SiGeO₂ or GeO₂ layer 974.

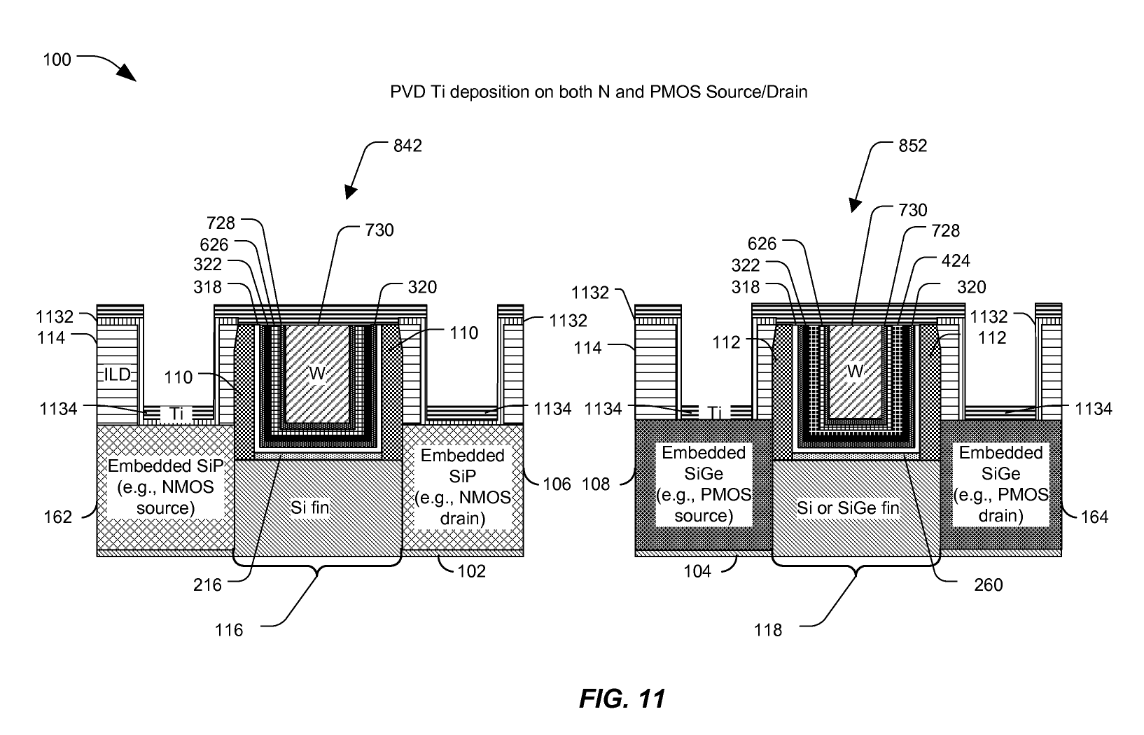

Referring to FIG. 11, a diagram of a side view of a structure as formed during a process of fabricating an electronic device is disclosed. A material layer (e.g., a Ti layer 1134) may be deposited on the structure 100. For example, the material layer (e.g., the Ti layer 1134) may be deposited using physical vapor deposition (PVD) subsequent to removal of the native SiGeO₂ or GeO₂ layer 974. A portion of the Ti layer 1134 may react with the native SiO₂ layer on the drain region 106 and the source region 162 to form a titanium dioxide (TiO₂) layer 1132. The TiO₂ layer 1132 may be formed on a surface of the ILD 114.

The material layer (e.g., the Ti layer 1134) may be deposited on the source region 162 and the drain region 106 such that the amorphous NMOS remains unannealed. For example, the material layer (e.g., the Ti layer 1134) may be deposited on the source region 162 and the drain region 106 such that a temperature of the amorphous NMOS work-function metal layer 626 remains below a crystallization temperature of the amorphous NMOS work-function metal layer 626. To illustrate, depositing the Ti layer 1134 using PVD may not raise a temperature of the amorphous NMOS work-function metal layer 626 to the crystallization temperature of the amorphous NMOS work-function metal layer 626 (i.e., the temperature of the amorphous NMOS work-function metal layer 626 remains below the crystallization temperature so that the metal remains in an amorphous state). The Ti layer 1134 is stable without high temperature annealing. The Ti layer 1134 may remain unannealed to maintain the temperature of the amorphous NMOS work-function metal layer 626 below the crystallization temperature of the amorphous NMOS work-function metal layer 626.

The material layer (e.g., the Ti layer 1134) may be deposited on the source region 108 and the drain region 164 such that the amorphous NMOS work-function metal layer 626 and the amorphous PMOS work-function metal layer 424 remain unannealed. For example, the material layer (e.g., the Ti layer 1134) may be deposited on the source region 108 and the drain region 164 such that a deposition temperature is below a first crystallization temperature of the amorphous NMOS work-function metal layer 626 and is below a second crystallization temperature of the amorphous PMOS work-function metal layer 424. To illustrate, depositing the Ti layer 1134 using PVD may not raise a first temperature of the amorphous NMOS work-function metal layer 626 to the first crystallization temperature and may not raise a second temperature of the amorphous PMOS work-function metal layer 424 to the second crystallization temperature so that the metal remains in an amorphous state.

Even if the temperature of the amorphous NMOS work-function metal layer 626 increases during deposition of the Ti layer 1134, the temperature of the amorphous NMOS work-function metal layer 626 may remain below the first crystallization temperature. Even if the temperature of the amorphous PMOS work-function metal layer 424 increases during deposition of the Ti layer 1134, the temperature of the amorphous PMOS work-function metal layer 424 may remain below the second crystallization temperature. The amorphous NMOS work-function metal layer 626 and the amorphous PMOS work-function metal layer 424 may remain amorphous subsequent to deposition of the material layer (e.g., the Ti layer 1134) on the source regions and the drain regions.

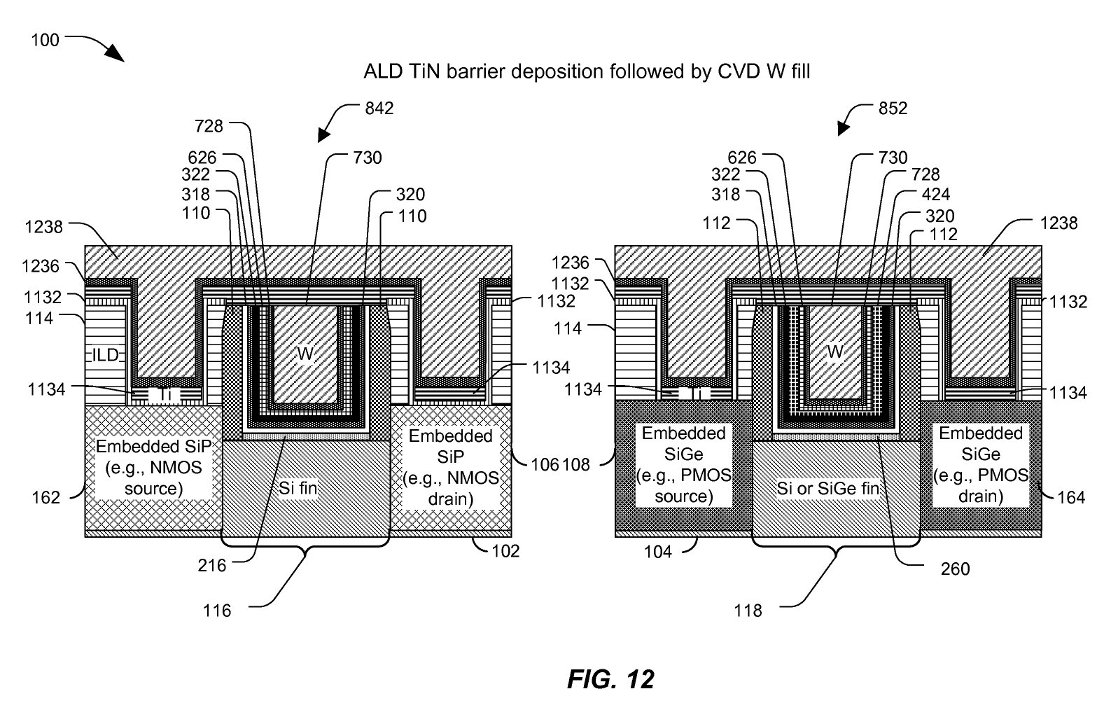

Referring to FIG. 12, a diagram of a side view of a structure as formed during a process of fabricating an electronic device is disclosed. A TiN barrier layer 1236 may be deposited on the structure 100. For example, the TiN barrier layer 1236 may be deposited using ALD subsequent to formation of the TiO₂ layer 1132. A tungsten (W) layer 1238 may be deposited on the TiN barrier layer 1236 using CVD.

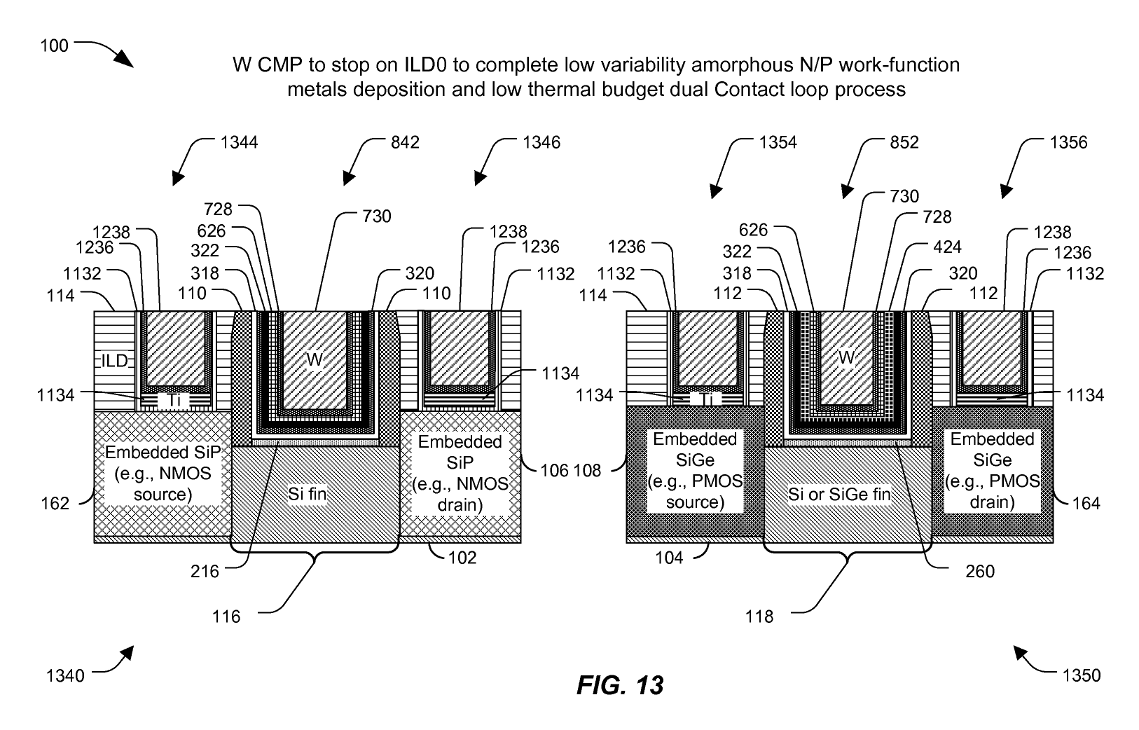

Referring to FIG. 13, a diagram of a side view of a structure as formed during a process of fabricating an electronic device is disclosed. CMP may be performed on the structure 100. For example, a source contact 1344 (e.g., an n-type source (N-source)), a drain contact 1346 (e.g., an n-type drain (N-drain)), a source contact 1354 (e.g., a p-type source (P-source)), and a drain contact 1356 (e.g., a p-type drain (P-drain)) may be formed by performing CMP on the W layer 1238 to the ILD 114.

Each of the source contact 1344 and the drain contact 1346 may include the Ti layer 1134, the TiN barrier layer 1236, and the W layer 1238. The source contact 1344 may be coupled via the TiO₂ layer 1132 to the source region 162. The drain contact 1346 may be coupled via the TiO₂ layer 1132 to the drain region 106. Each of the source contact 1354 and the drain contact 1356 may include the Ti layer 1134, the TiN barrier layer 1236, and the W layer 1238. The source contact 1354 may be coupled to the source region 108. The drain contact 1356 may be coupled to the drain region 164. At least one of the source contact 1344, the drain contact 1346, the source contact 1354, and the drain contact 1356 may exclude a silicide material. For example, the source contact 1344 may be coupled via the TiO₂ layer 1132 to the source region 162 without an intervening silicide layer. The drain contact 1346 may be coupled via the TiO₂ layer 1132 to the drain region 106 without an intervening silicide layer. The Ti layer 1134 of the source contact 1354 may be coupled to the source region 108 without an intervening silicide layer. The Ti layer 1134 of the drain contact 1356 may be coupled to the drain region 164 without an intervening silicide layer.

When annealing is performed during fabrication of a metal-gate transistor, the metal-gate transistor may include a silicide layer that is formed as a result of annealing a metal. The structure 100 is formed without annealing the Ti layer 134 and may exclude the silicide layer. The Ti layer 1134 may be unannealed because Ti is stable without high temperature annealing.

An NMOS transistor 1340 includes the metal-gate 842, the source contact 1344, and the drain contact 1346. A PMOS transistor 1350 includes the metal-gate 852, the source contact 1354, and the drain contact 1356. Each of the metal-gates 842 and 852 of the structure 100 include the amorphous NMOS work-function metal layer 626. The metal-gate 852 may include the amorphous PMOS work-function metal layer 424. The amorphous NMOS work-function metal layer 626 and the amorphous PMOS work-function metal layer 424 are unannealed metal layers. The NMOS transistor 1340 and the PMOS transistor 1350 may have reduced work function variation as a result of having the amorphous NMOS work-function metal layer 626 and the amorphous PMOS work-function metal layer 424.

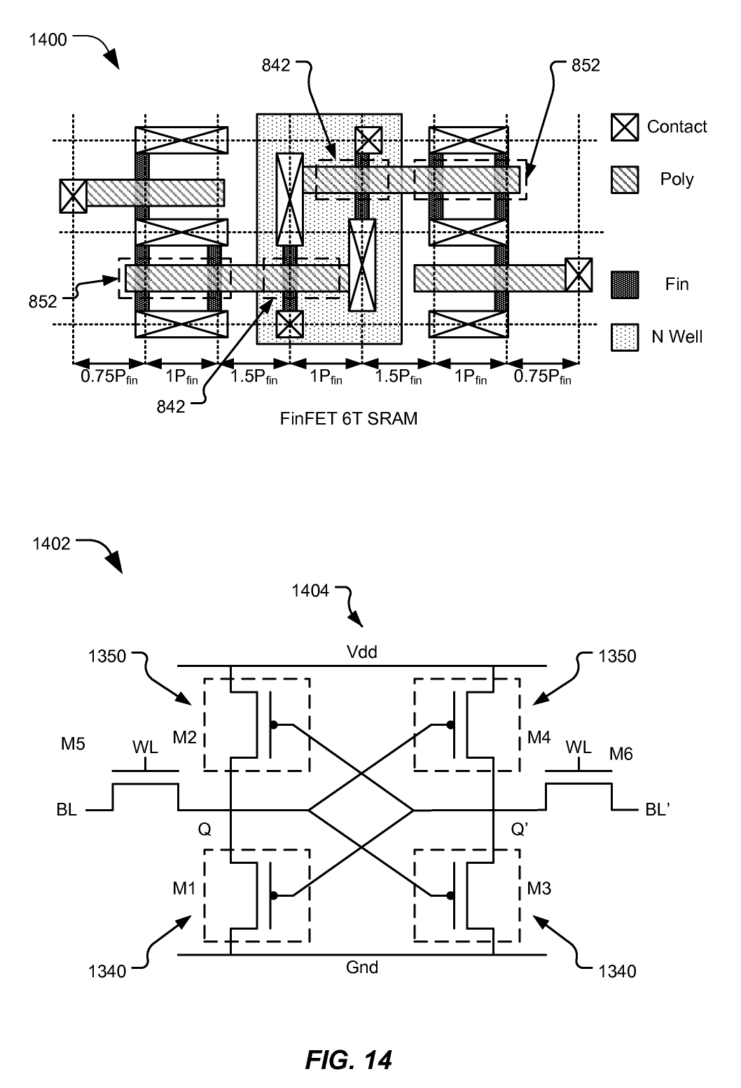

Referring to FIG. 14, an illustrative diagram of a static random access memory (SRAM) cell is shown and generally designated 1400. In a particular embodiment, the SRAM cell 1400 may include the NMOS transistor 1340, the PMOS transistor 1350, or both, of FIG. 13.

The SRAM cell 1400 may include a particular number (e.g., 6 or 8) of transistors. As illustrated in FIG. 1, the SRAM cell 1400 may include 6 fin-shaped field effect transistors (FinFETs). In another embodiment, the SRAM cell 1400 may include fewer transistors or more transistors. The SRAM cell 1400 may include two pass transistors, two NMOS transistors, and two PMOS transistors. At least one of the NMOS transistors may correspond to the NMOS transistor 1340 of FIG. 13. For example, at least one of the NMOS transistors may include the metal-gate 842. At least one of the PMOS transistors may correspond to the PMOS transistor 1350 of FIG. 13. For example, at least one of the PMOS transistors may include the metal-gate 852.

The metal-gate 842 may include the amorphous NMOS work-function metal layer 626 and thus have reduced work function variation. The metal-gate 852 may include the amorphous NMOS work-function metal layer 626 and the amorphous PMOS work-function metal layer 424 and thus have reduced work function variation. Reduced work function variation may result in reduced Vt fluctuation.

FIG. 14 also includes an illustrative circuit diagram 1402 of the SRAM cell 1400. The SRAM cell 1400 may include the metal-gate 842, the metal-gate 852, or both, and may thus have reduced work function variation and reduced Vt fluctuation. The reduced Vt fluctuation may result in the SRAM cell 1400 having a lower supply voltage (Vdd) 1404, thereby reducing power consumption of the SRAM cell 1400. FIG. 14 illustrates the SRAM cell 1400 including the metal-gate 842 and the metal-gate 852. In other embodiments, the metal-gate 842, the metal-gate 852, or both, may be included in a transistor of a memory device, a logic device, a semi-conductor device, an integrated circuit, etc.

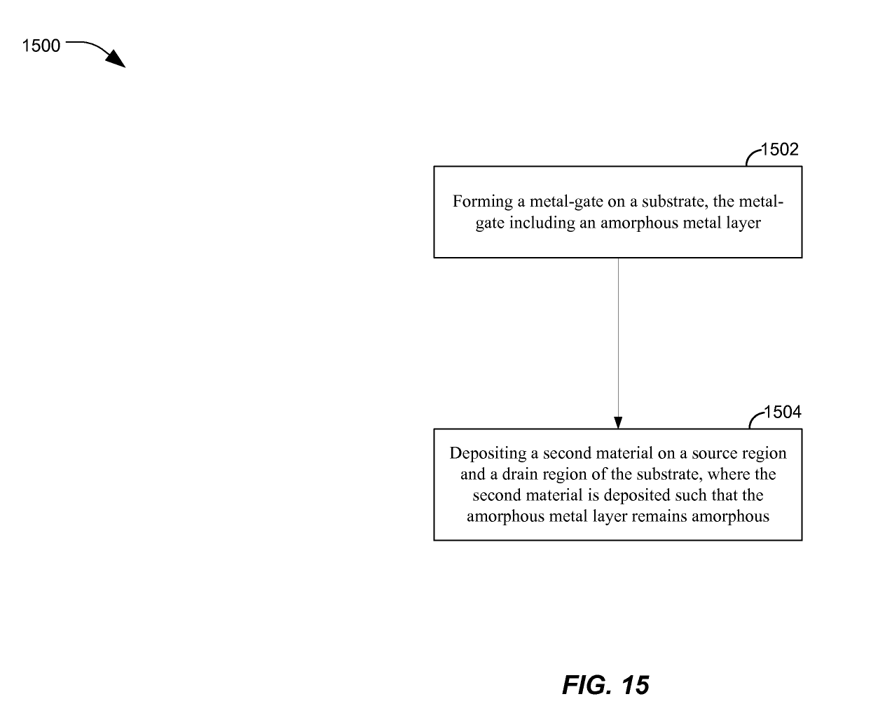

FIG. 15 is a flow chart illustrating a particular embodiment of a method 1500 of fabricating a semiconductor device. In a particular embodiment, the semiconductor device may include the structure 100 of FIG. 13.

The method 1500 includes forming a metal-gate on a substrate, at 1502. For example, the metal-gate 842 may be formed on the Si fin 102, and/or the metal-gate 852 may be formed on the Si or SiGe fin 104, as described with reference to FIGS. 1-8. The metal-gate 842 may include the amorphous NMOS work-function metal layer 626 having a first crystallization temperature, as described with reference to FIG. 8. The metal-gate 852 may include the amorphous NMOS work-function metal layer 626 having the first crystallization temperature and the amorphous PMOS work-function metal layer 424 having a second crystallization temperature, as described with reference to FIG. 8.

The metal-gate 842 may have a first number of amorphous work-function metal layers and the metal-gate 852 may have a second number of amorphous work-function metal layers. A first threshold voltage of the metal-gate 842 may be based on the first number of amorphous work-function metal layers. A second threshold voltage of the metal-gate 852 may be based on the second number of amorphous work-function metal layers. When the first number and the second number are distinct, the first threshold voltage and the second threshold voltage may be distinct. In a particular embodiment, the metal-gate 852 may include one of the amorphous PMOS work-function metal layer 424 or the amorphous NMOS work-function metal layer 626. In this embodiment, the metal-gate 842 may include the amorphous PMOS work-function metal layer 424 and the amorphous NMOS work-function metal layer 626.

The method 1500 also includes depositing a second material on a source region and a drain region of the substrate, at 1504. The second material may be deposited such that the amorphous metal layer remains amorphous. The amorphous metal layer may remain amorphous because a temperature of the amorphous metal layer remains below a crystallization temperature of the amorphous metal layer during deposition of the second material. For example, the Ti layer 1134 may be deposited on the source region 162 and the drain region 106, as described with reference to FIG. 11. The Ti layer 1134 may be deposited such that a temperature of the amorphous NMOS work-function metal layer 626 remains below a first crystallization temperature of the amorphous NMOS work-function metal layer 626 to prevent crystallization of the amorphous NMOS work-function metal layer 626. Thus, the amorphous NMOS work-function metal layer 626 may remain amorphous and the Ti layer 1134 may remain unannealed.

As another example, the Ti layer 1134 may be deposited on the source region 108 and the drain region 164, as described with reference to FIG. 11. The Ti layer 1134 may be deposited such that a first temperature of the amorphous NMOS work-function metal layer 626 remains below a first crystallization temperature of the amorphous NMOS work-function metal layer 626 and a second temperature of the amorphous PMOS work-function metal layer 424 remains below a second crystallization temperature of the amorphous PMOS work-function metal layer 424 to prevent crystallization of the amorphous NMOS work-function metal layer 626 and the amorphous PMOS work-function metal layer 424. For example, the Ti layer 1134 may remain unannealed, the amorphous NMOS work-function metal layer 626 may remain amorphous, and the amorphous PMOS work-function metal layer 424 may remain amorphous.

The method 1500 may thus enable fabrication of a semiconductor device (e.g., a transistor) including a metal-gate having an amorphous metal layer. The semiconductor device may thus have reduced work function variation and reduced power consumption, as compared to a semiconductor device without an amorphous metal-gate.

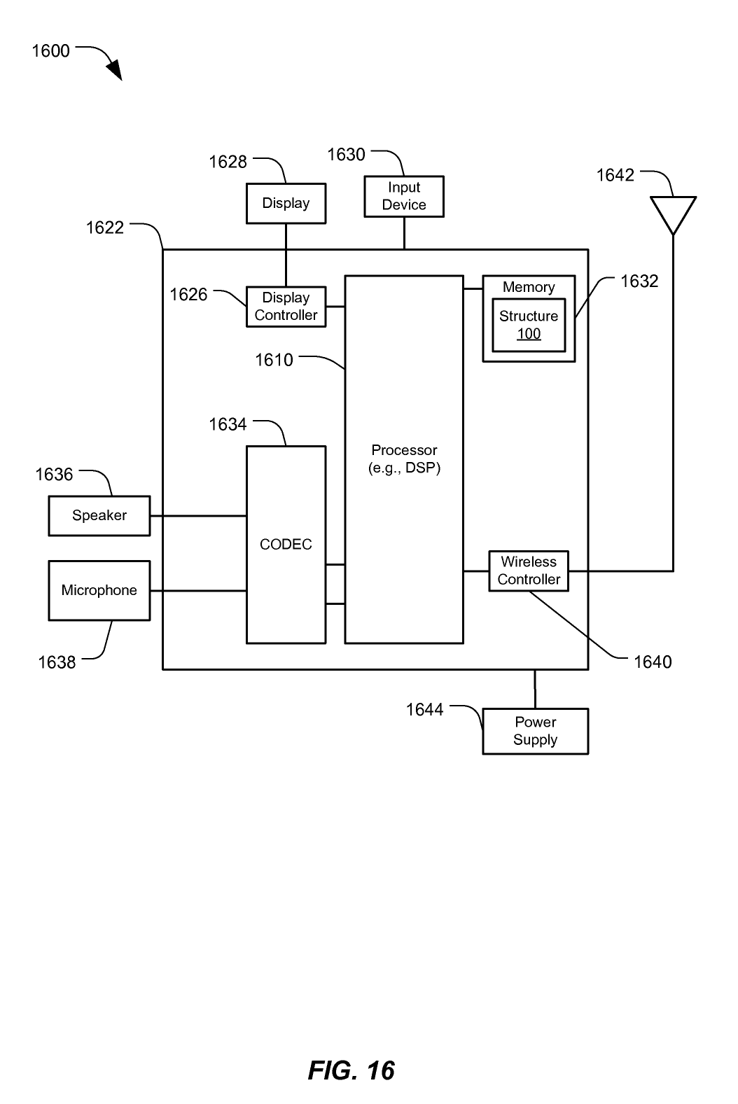

Referring to FIG. 16, a block diagram of a particular illustrative embodiment of a wireless communication device is depicted and generally designated 1600. The wireless communication device 1600 includes a processor 1610, such as a digital signal processor (DSP), coupled to a memory 1632 (e.g., a random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art). The memory 1632 may include a storage medium that stores instructions executable by the processor 1610. The memory 1632 may store data accessible to the processor 1610.

The wireless communication device 1600 includes the structure 100 that includes an amorphous metal-gate. For example, as depicted in FIG. 16, the memory 1632 may include the structure 100 having an amorphous metal-gate. In a particular embodiment, the memory 1632, the processor 1610, and/or another component of the wireless communication device 1600 may include one or more of the NMOS transistor 1340, the PMOS transistor 1350 of FIG. 13, or both. For example, the memory 1632 may include an array of memory cells. Each memory cell of the array may include the NMOS transistor 1340, the PMOS transistor 1350, or both.

FIG. 16 also shows a display controller 1626 that is coupled to the processor 1610 and to a display 1628. A coder/decoder (CODEC) 1634 may also be coupled to the processor 1610. A speaker 1636 and a microphone 1638 may be coupled to the CODEC 1634. FIG. 16 also indicates that a wireless controller 1640 may be coupled to the processor 1610 and may be further coupled to an antenna 1642.

In a particular embodiment, the processor 1610, the display controller 1626, the memory 1632, the CODEC 1634, and the wireless controller 1640 are included in a system-in-package or system-on-chip device 1622. In a particular embodiment, an input device 1630 and a power supply 1644 are coupled to the system-on-chip device 1622. Moreover, in a particular embodiment, as illustrated in FIG. 16, the display 1628, the input device 1630, the speaker 1636, the microphone 1638, the wireless antenna 1642, and the power supply 1644 are external to the system-on-chip device 1622. However, each of the display 1628, the input device 1630, the speaker 1636, the microphone 1638, the antenna 1642, and the power supply 1644 may be coupled to a component of the system-on-chip device 1622, such as an interface or a controller.

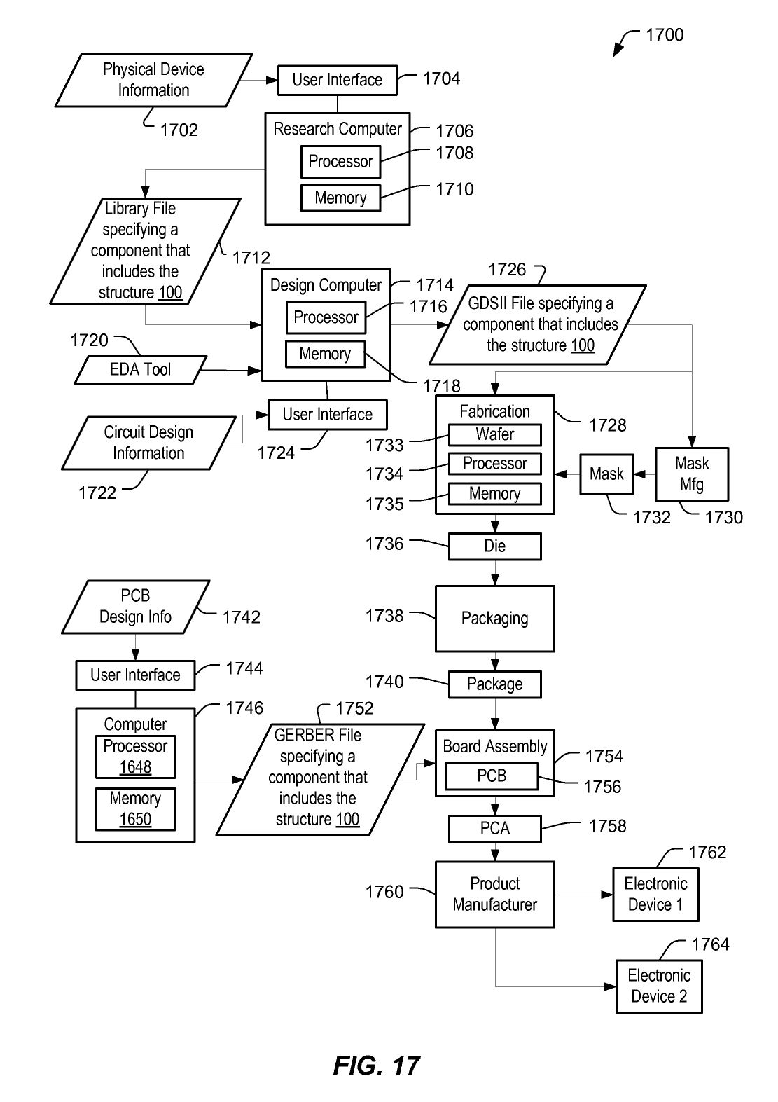

The foregoing disclosed devices and functionalities may be designed and configured into computer files (e.g. RTL, GDSII, GERBER, etc.) stored on computer readable media. Some or all such files may be provided to fabrication handlers who fabricate devices based on such files. Resulting products include wafers that are then cut into die and packaged into a chip. The chips are then integrated into electronic devices (e.g., a memory device, a logic device, a semiconductor device, an integrated circuit, another device that includes a transistor, etc.), as described further with reference to FIG. 17.

Referring to FIG. 17, a particular illustrative embodiment of an electronic device manufacturing (e.g., fabricating) process is depicted and generally designated 1700. Physical device information 1702 is received at the manufacturing process 1700, such as at a research computer 1706. The physical device information 1702 may include design information representing at least one physical property of an electronic device that includes an amorphous metal-gate, such as the structure 100 of FIG. 13. For example, the physical device information 1702 may include physical parameters, material characteristics, and structure information that is entered via a user interface 1704 coupled to the research computer 1706. The research computer 1706 includes a processor 1708, such as one or more processing cores, coupled to a computer-readable medium (e.g., a non-transitory computer-readable medium), such as a memory 1710. The memory 1710 may store computer-readable instructions that are executable to cause the processor 1708 to transform the physical device information 1702 to comply with a file format and to generate a library file 1712.

In a particular embodiment, the library file 1712 includes at least one data file including the transformed design information. For example, the library file 1712 may include a library of semiconductor devices including the structure 100 having an amorphous metal-gate. The library file 1712 may be provided for use with an electronic design automation (EDA) tool 1720.

The library file 1712 may be used in conjunction with the EDA tool 1720 at a design computer 1714 including a processor 1716, such as one or more processing cores, coupled to a memory 1718. The EDA tool 1720 may be stored as processor executable instructions at the memory 1718 to enable a user of the design computer 1714 to design a circuit including the structure 100 having an amorphous metal-gate using the library file 1712. For example, a user of the design computer 1714 may enter circuit design information 1722 via a user interface 1712 coupled to the design computer 1714. The circuit design information 1722 may include design information representing at least one physical property of the electronic device that includes an amorphous metal-gate, such as the structure 100 of FIG. 13. To illustrate, the circuit design property may include identification of particular circuits and relationships to other elements in a circuit design, positioning information, feature size information, stress relief region information, SMS information, interconnection information, or other information representing a physical property of a semiconductor device.

The design computer 1714 may be configured to transform the design information, including the circuit design information 1722, to comply with a file format. To illustrate, the file format may include a database binary file format representing planar geometric shapes, text labels, and other information about a circuit layout in a hierarchical format, such as a Graphic Data System (GDSII) file format. The design computer 1714 may be configured to generate a data file including the transformed design information, such as a GDSII file 1726 that includes information describing the electronic device that includes an amorphous metal-gate, such as the structure 1300 of FIG. 13, in addition to other circuits or information. To illustrate, the data file may include information corresponding to a system-on-chip (SOC) that includes the electronic device that includes an amorphous metal-gate, such as the structure 100 of FIG. 13, and that also includes additional electronic circuits and components within the SOC.

The GDSII file 1726 may be received at a fabrication process 1728 to fabricate an electronic device that includes an amorphous metal-gate, such as the structure 100 of FIG. 13, according to transformed information in the GDSII file 1726. For example, a device manufacturing process may include providing the GDSII file 1726 to a mask manufacturer 1730 to create one or more masks, such as masks to be used with photolithography processing, illustrated as a representative mask 1732. The mask 1732 may be used during the fabrication process to generate one or more wafers 1733, which may be tested and separated into dies, such as a representative die 1736. The die 1736 includes a circuit including the electronic device that includes an amorphous metal-gate, such as the structure 100 of FIG. 13.

For example, the fabrication process 1728 may include a processor 1734 and a memory 1735 to initiate and/or control the fabrication process 1728. The memory 1735 may include executable instructions such as computer-readable instructions or processor-readable instructions. The executable instructions may include one or more instructions that are executable by a computer such as the processor 1734.

The fabrication process 1728 may be implemented by a fabrication system that is fully automated or partially automated. For example, the fabrication process 1728 may be automated according to a schedule. The fabrication system may include fabrication equipment (e.g., processing tools) to perform one or more operations to form a semiconductor device. For example, the fabrication equipment may be configured to deposit one or more materials using chemical vapor deposition (CVD) and/or physical vapor deposition (PVD), pattern materials using a single-mask or multi-mask litho-etch process (e.g., two-mask LELE), pattern materials using a litho-freeze-litho-etch (LFLE) process, pattern materials using a self-aligned double patterning (SADP) process, epitaxially grow one or more materials, conformally deposit one or more materials, apply a hardmask, apply an etching mask, perform etching, perform planarization, form a dummy gate stack, form a gate stack, perform a standard clean 1 type, etc. In a particular embodiment, the fabrication process 1728 corresponds to a semiconductor manufacturing process associated with a technology node smaller than 14 nm (e.g., 10 nm, 7 nm, etc.). The specific process or combination of processes used to manufacture a device (e.g., including the structure 100 of FIG. 13) may be based on design constraints and available materials/equipment. Thus, in particular embodiments, different processes may be used than described with reference to FIGS. 1-17 during manufacture of the device.

As an illustrative example, a two-mask LELE process used during Vial formation for the structure 100 may include using a first photoresist mask to form a first pattern on a first layer (e.g., a nitride layer) of a device and etching the first pattern. A second mask may then be used to form a second pattern on the device and the combined pattern may be etched down to a second, lower layer (e.g., an oxide layer) of the device. In the combined pattern, features (e.g., lines) of the first pattern and the second pattern may be interleaved. The combined pattern may thus have smaller feature (e.g., line) pitch as compared to the first pattern and the second pattern.

As another illustrative example, a SADP process used to pattern an M1 or M2 layer of the structure 100 may include forming a “dummy” pattern on a device. A conforming dielectric layer may be formed (e.g., deposited) over the dummy pattern and may be etched. During etching, all of the dielectric layer except “spacers” of dielectric material adjacent to sidewalls of the dummy pattern may be removed. The dummy pattern may then be removed (e.g., without etching), leaving behind the spacers, which may form a pattern that has higher feature (e.g., line) density than the dummy pattern. The higher-density spacer pattern may be used to pattern the M1 or M2 layer.

The fabrication system (e.g., an automated system that performs the fabrication process 1728) may have a distributed architecture (e.g., a hierarchy). For example, the fabrication system may include one or more processors, such as the processor 1734, one or more memories, such as the memory 1735, and/or controllers that are distributed according to the distributed architecture. The distributed architecture may include a high-level processor that controls or initiates operations of one or more low-level systems. For example, a high-level portion of the fabrication process 1728 may include one or more processors, such as the processor 1734, and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the particular high-level. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component may include a processor, such as the processor 1734.

Alternatively, the processor 1734 may be a part of a high-level system, subsystem, or component of the fabrication system. In another embodiment, the processor 1734 includes distributed processing at various levels and components of a fabrication system.

The executable instructions included in the memory 1735 may enable the processor 1734 to form (or initiate formation of) the structure 100. In a particular embodiment, the memory 1735 is a non-transitory computer-readable medium storing computer-executable instructions that are executable by the processor 1734 to cause the processor 1734 to initiate formation of a device in accordance with at least a portion of the operations described with reference to FIGS. 1-13. For example, the computer executable instructions may be executable to cause the processor 1734 to initiate formation of the structure 100. As an illustrative example, the processor 1734 may initiate or control one or more of the operations described with reference to FIGS. 1-13.

The die 1736 may be provided to a packaging process 1738 where the die 1736 is incorporated into a representative package 1740. For example, the package 1740 may include the single die 1736 or multiple dies, such as a system-in-package (SiP) arrangement. The package 1740 may be configured to conform to one or more standards or specifications, such as Joint Electron Device Engineering Council (JEDEC) standards.

Information regarding the package 1740 may be distributed to various product designers, such as via a component library stored at a computer 1746. The computer 1746 may include a processor 1748, such as one or more processing cores, coupled to a memory 1750. A printed circuit board (PCB) tool may be stored as processor executable instructions at the memory 1750 to process PCB design information 1742 received from a user of the computer 1746 via a user interface 1744. The PCB design information 1742 may include physical positioning information of a packaged semiconductor device on a circuit board, the packaged semiconductor device corresponding to the package 1740 including the structure 100 of FIG. 13.

The computer 1746 may be configured to transform the PCB design information 1742 to generate a data file, such as a GERBER file 1752 with data that includes physical positioning information of a packaged semiconductor device on a circuit board, as well as layout of electrical connections such as traces and vias, where the packaged semiconductor device corresponds to the package 1740 including the structure 100 of FIG. 13. In other embodiments, the data file generated by the transformed PCB design information may have a format other than a GERBER format.

The GERBER file 1752 may be received at a board assembly process 1754 and used to create PCBs, such as a representative PCB 1756, manufactured in accordance with the design information stored within the GERBER file 1752. For example, the GERBER file 1752 may be uploaded to one or more machines to perform various steps of a PCB production process. The PCB 1756 may be populated with electronic components including the package 1740 to form a representative printed circuit assembly (PCA) 1758.

The PCA 1758 may be received at a product manufacturing process 1760 and integrated into one or more electronic devices, such as a first representative electronic device 1762 and a second representative electronic device 1764. For example, the first representative electronic device 1762, the second representative electronic device 1764, or both, may include or correspond to the wireless communication device 1600 of FIG. 16. As an illustrative, non-limiting example, the first representative electronic device 1762, the second representative electronic device 1764, or both, may include a communications device, a fixed location data unit, a mobile location data unit, a mobile phone, a cellular phone, a satellite phone, a computer, a tablet, a portable computer, or a desktop computer. Alternatively or additionally, the first representative electronic device 1762, the second representative electronic device 1764, or both, may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof, into which the structure including an amorphous metal-gate, such as the structure 100 of FIG. 13, is integrated.

As another illustrative, non-limiting example, one or more of the electronic devices 1762 and 1764 may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 17 illustrates remote units according to teachings of the disclosure, the disclosure is not limited to these illustrated units. Embodiments of the disclosure may be suitably employed in any device which includes active integrated circuitry including memory and on-chip circuitry. For example, one or more of the electronic device 1762 and 1764 may include cars, trucks, airplanes, boats, other vehicles, or appliances, such as refrigerators, microwaves, washing machines, security systems, other appliances, or a combination thereof. In a particular embodiment, one or more of the electronic device 1762 and 1764 may utilize memory and/or wireless communication.

A device that includes a semiconductor device including the structure having an amorphous metal-gate, such as the structure 100 of FIG. 13, may be fabricated, processed, and incorporated into an electronic device, as described in the illustrative process 1700. One or more aspects of the embodiments disclosed with respect to FIGS. 1-16 may be included at various processing stages, such as within the library file 1712, the GDSII file 1726 (e.g., a file having a GDSII format), and the GERBER file 1752 (e.g., a file having a GERBER format), as well as stored at the memory 1710 of the research computer 1706, the memory 1718 of the design computer 1714, the memory 1750 of the computer 1746, the memory of one or more other computers or processors (not shown) used at the various stages, such as at the board assembly process 1754, and also incorporated into one or more other physical embodiments such as the mask 1732, the die 1736, the package 1740, the PCA 1758, other products such as prototype circuits or devices (not shown), or any combination thereof. Although various representative stages of production from a physical device design to a final product are depicted, in other embodiments fewer stages may be used or additional stages may be included. Similarly, the process 1700 may be performed by a single entity or by one or more entities performing various stages of the process 1700.

Although one or more of FIGS. 1-17 may illustrate systems, devices, and/or methods according to the teachings of the disclosure, the disclosure is not limited to these illustrated systems, devices, and/or methods. Embodiments of the disclosure may be suitably employed in any device that includes integrated circuitry including memory, a processor, and on-chip circuitry.

One or more functions or components of any of FIGS. 1-17 as illustrated or described herein may be combined with one or more other portions of another of FIGS. 1-17. Accordingly, no single embodiment described herein should be construed as limiting and embodiments of the disclosure may be suitably combined without departing form the teachings of the disclosure.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and a storage device may reside as discrete components in a computing device or user terminal A storage device is not a signal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A semiconductor device comprising:
a substrate including a source region, a drain region, and a channel;
a source contact coupled to the source region;
a drain contact coupled to the drain region; and
a metal-gate coupled to the channel, the metal-gate including an amorphous metal layer.

2. The semiconductor device of claim 1, wherein the source contact and the drain contact exclude a silicide material.

3. The semiconductor device of claim 1, wherein the amorphous metal layer is unannealed.

4. The semiconductor device of claim 1, wherein the source contact and the drain contact are formed by depositing titanium (Ti) on the source region and the drain region of the substrate, and wherein the Ti is deposited such that a temperature of the amorphous metal layer remains below a crystallization temperature of the amorphous metal layer.

5. The semiconductor device of claim 1, wherein the source contact includes a first titanium layer and the drain contact includes a second titanium (Ti) layer.

6. The semiconductor device of claim 5, wherein the substrate includes a silicon (Si) fin, wherein the source region includes a first silicon phosphorous (SiP) layer embedded in a first portion of the Si fin, and wherein the drain region includes a second SiP layer embedded in a second portion of the Si fin.

7. The semiconductor device of claim 6, wherein the source contact is coupled via a first titanium dioxide (TiO₂) layer to the first SiP layer and the drain contact is coupled via a second TiO₂ layer to the second SiP layer.

8. The semiconductor device of claim 1, wherein the substrate includes a silicon (Si) fin, wherein the source region includes a first silicon germanium (SiGe) layer embedded in a first portion of the Si fin, and wherein the drain region includes a second SiGe layer embedded in a second portion of the Si fin.

9. The semiconductor device of claim 1, wherein the substrate includes a silicon germanium (SiGe) fin, wherein the source region includes a first SiGe layer embedded in a first portion of the SiGe fin, and wherein the drain region includes a second SiGe layer embedded in a second portion of the SiGe fin.

10. The semiconductor device of claim 1, wherein the amorphous metal layer includes a metal, a metal alloy, or an intermetallic layer, and wherein the amorphous metal layer includes at least one of tungsten (W), tantalum (Ta), aluminum (Al), cobalt (Co), titanium (Ti), and platinum (Pt).

11. The semiconductor device of claim 10, wherein the amorphous metal layer includes at least one of silicon (Si), carbon (C), and nitrogen (N).

12. A method of fabricating a semiconductor device comprising:
forming a metal-gate on a substrate, the metal-gate including an amorphous metal layer; and
depositing a second material on a source region and a drain region of the substrate, the second material deposited such that the amorphous metal layer remains amorphous.

13. The method of claim 12, wherein forming the metal-gate includes:
removing an amorphous silicon (Si) dummy gate from the substrate,
forming a silicon dioxide (SiO₂) layer on the substrate, and
depositing a high dielectric constant (high-K) layer on the SiO₂ layer,
wherein the substrate includes an Si fin.

14. The method of claim 13, wherein forming the metal-gate includes depositing a titanium nitride (TiN) layer on the high-K layer.

15. The method of claim 14, wherein forming the metal-gate includes depositing a tantalum nitride (TaN) barrier layer on the TiN layer.

16. The method of claim 15, wherein forming the metal-gate includes depositing the amorphous metal layer on the TaN barrier layer.

17. The method of claim 16, wherein forming the metal-gate includes depositing a TiN barrier layer on the amorphous metal layer.

18. The method of claim 17, wherein forming the metal-gate includes depositing a tungsten (W) layer on the TiN barrier layer.

19. The method of claim 12, further comprising:
etching a first recess in a first inter-layer dielectric (ILD) layer,
wherein the substrate includes a silicon (Si) fin,
wherein the source region includes a first silicon phosphorous (SiP) layer embedded in a first portion of the Si fin, and
wherein the first ILD layer is on the source region; and
forming a first silicon dioxide (SiO₂) layer on the first SiP layer.

20. The method of claim 19, further comprising:
etching a second recess in a second ILD layer,
wherein the drain region includes a second SiP layer embedded in a second portion of the Si fin, and
wherein the second ILD layer is on the drain region; and
forming a second SiO₂ layer on the second SiP layer.

21. The method of claim 20, wherein the second material is deposited in the first recess and the second recess, and wherein the second material includes titanium (Ti).

22. The method of claim 12, further comprising:
etching a first recess in a first interlayer dielectric (ILD) layer,
wherein the substrate includes a silicon (Si) fin,
wherein the source region includes a first silicon germanium (SiGe) layer embedded in a first portion of the Si fin, and
wherein the first ILD layer is on the source region; and
forming a first silicon germanium dioxide (SiGeO₂) layer on the first SiGe layer.

23. The method of claim 22, further comprising:
etching a second recess in a second ILD layer,
wherein the drain region includes a second SiGe layer embedded in a second portion of the Si fin, and
wherein the second ILD layer is on the drain region; and
forming a second SiGeO₂ layer on the second SiGe layer.

24. The method of claim 23, further comprising removing the first SiGeO₂ layer and the second SiGeO₂ layer prior to depositing the second material in the first recess and the second recess, wherein the second material includes titanium (Ti).

25. The method of claim 24, wherein the second material is deposited using physical vapor deposition (PVD).

26. The method of claim 24, further comprising depositing a titanium nitride (TiN) barrier layer on the second material.

27. The method of claim 26, further comprising filling the first recess and the second recess with tungsten (W).

28. A semiconductor device fabricated by a process comprising:
forming a metal-gate on a substrate, the metal-gate including an amorphous metal layer; and
depositing a second material on a source region and a drain region of the substrate, wherein the second material is deposited such that the amorphous metal layer remains amorphous.

29. The semiconductor device of claim 28, wherein the second material is deposited using physical vapor deposition (PVD).

30. The semiconductor device of claim 28, wherein the second material includes titanium (Ti).
